(19) United States
(12) Patent Application Publication
(10) Pub. No.: US 2016/0064630 A1
(43) Pub. Date: Mar. 3, 2016

(54) FLIP CHIP LED PACKAGE

(71) Applicant: Texas Instruments Incorporated, Dallas, TX (US)

(72) Inventor: ABRAM CASTRO, FORT WORTH, TX (US)

(21) Appl. No.: 14/818,969

(22) Filed: Aug. 5, 2015

Related U.S. Application Data
(60) Provisional application No. 62/041,702, filed on Aug. 26, 2014.

(51) Int. Cl. H01L 33/58; H01L 33/62; H01L 33/54; H01L 33/00; H01L 33/50

(52) U.S. Cl. CPC H01L 33/58; H01L 33/005; H01L 33/502; H01L 33/54; H01L 33/62; H01L 2933/0016; H01L 2933/0025; H01L 2933/0033; H01L 2933/0041; H01L 2933/0058; H01L 2933/0066

(57) ABSTRACT

A flip chip light emitting diode (LED) package includes an LED die having a first substrate, a p-type region and an n-type region including an active layer in between, a metal contact on the p-type region (anode contact) and a metal contact on the n-type region (cathode contact). A package substrate or lead frame includes a dielectric material that has a first metal through via (first metal post) and second metal through via (second metal post) spaced apart from one another and embedded in the dielectric material. A first metal pad is on a bottom side of the first metal post and a second metal pad is on a bottom side of the second metal post. An interconnect metal paste or metal ink residual (metal residual) is between the anode contact and first metal post and between the cathode contact and the second metal post.

### CROSS REFERENCE TO RELATED APPLICATIONS

This application claims the benefit of Provisional Application Ser. No. 62/041,702 entitled “Method for Low Cost Flip Chip LED Package” filed on Aug. 26, 2014, which is herein incorporated by reference in its entirety.

### FIELD

Disclosed embodiments relate to light emitting diode (LED) flip chip devices.

### BACKGROUND

A conventional blue ultraviolet (UV) or near-UV LED is formed on a growth substrate. In one example, the LED is a GaN-based LED, such as an AlInGaN LED. Typically, a relatively thick n-type GaN layer is grown on a sapphire or SiC growth substrate using conventional epitaxial growth techniques. The relatively thick GaN layer typically includes a low temperature nucleation layer and one or more additional layers to provide a low-defect lattice structure for the n-type cladding layer and the active layer. One or more n-type cladding layers are then formed over the thick n-type layer, followed by an active layer, one or more p-type cladding layers, and a p-type contact layer (for metallization).

Various techniques are used to provide electrical access to the anode and cathode of the LED. LED devices have historically been packaged in lead frame-based wire bond ceramic structures. In the formation of ceramic chip carriers, lead frames are normally bonded to a build-up layer ceramic substrate by well-known methods with subsequent connections being made to the leads of the lead frame from appropriate bond pads on the LED die secured to the ceramic substrate.

Wire bonding is conventionally used for its low cost, and ceramic substrates are used for their good thermal dissipation properties relative to plastics. An LED packaging change to a flip chip interconnect can be helpful because the flip chip configuration allows for improved thermal management and improved light intensity emitted through the backside (substrate) of the LED die. In a known flip-chip LED example, portions of the p-layers and active layer are etched away to expose the n-layer for metallization. In this way the p-contact and n-contact are on the same side of the LED die and can be directly electrically attached to the contact pads of the package (or submount) using solder bumps, such as Au/Sn bumps. However, solder bumping methods for LED flip chip interconnects are generally too expensive to be practical in industry.

### SUMMARY

This Summary is provided to introduce a brief selection of disclosed concepts in a simplified form that are further described below in the Detailed Description including the drawings provided. This Summary is not intended to limit the claimed subject matter's scope.

Disclosed embodiments include flip chip light emitting diode (LED) packages including an LED die comprising a first substrate including a p-type region and an n-type region including an active layer in between, a metal contact on the p-type region (anode contact), and a metal contact on the n-type region (cathode contact). A package substrate or lead frame package includes a dielectric material that has a first metal through via (first metal post) and second metal through via (second metal post) spaced apart from one another and embedded in the dielectric material. A first metal pad is on a bottom side of the first metal post and a second metal pad is on a bottom side of the second metal post. An interconnect metal paste or metal ink residual (metal residual) is between the anode contact and the first metal post and between the cathode contact and the second metal post.

A metal paste as used herein refers to a metal system suspended in a carrier medium referred to as a flux. A metal ink as used herein refers to a solvent, metal particles and a dispersant. The metal paste or metal ink form the metal residual interconnect between the LED contacts and metal posts or leads of the package substrate during a reflow process in the case of a metal paste or a sintering process in the case of a metal ink (both well known in the industry).

### BRIEF DESCRIPTION OF THE DRAWINGS

Reference will now be made to the accompanying drawings, which are not necessarily drawn to scale, wherein:

FIG. 1 is a flow chart that shows steps in an example metal paste interconnect-based method for assembling a flip chip LED package, according to an example embodiment.

FIG. 2 is a cross sectional view of an example flip chip LED package, according to an example embodiment.

FIG. 3 is a cross sectional view of an example flip chip LED package that includes build-up layer ceramic package substrate, according to another example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

Disclosed flip chip LED packages utilize a metal interconnect paste applied directly to the package substrate or lead frame for high reliability LED die attachment of its anode and cathode contacts to contact pads of a package substrate or lead frame without the need for conventional (e.g., Au/Sn) bumps. Although a variety of different package substrates can be used, in one embodiment the package substrate can comprise an organic substrate designed for good thermal dissipation and low cost rather than the conventional relatively high cost ceramic substrate.

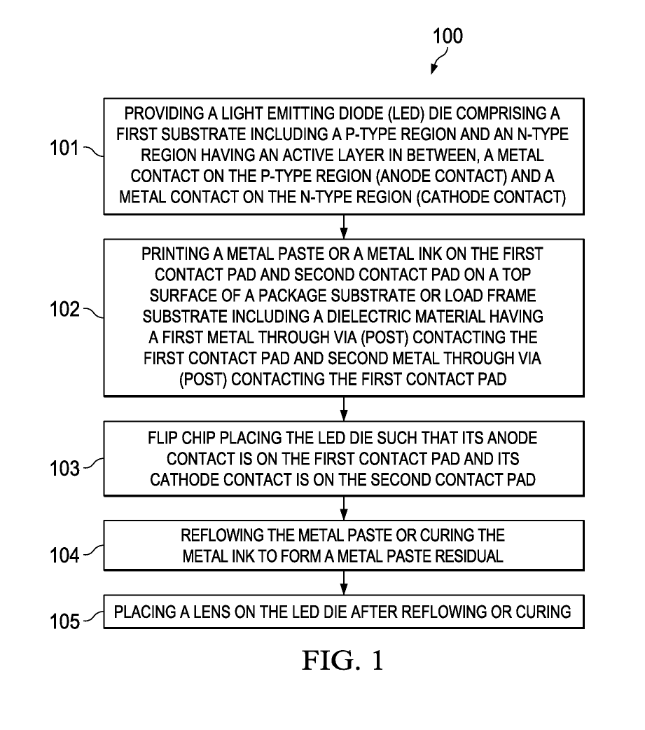

FIG. 1 is a flow chart that shows steps in an example metal paste interconnect-based method 100 for assembling a flip chip LED package, according to an example embodiment. Step 101 comprises providing an LED die comprising a first substrate including a p-type region and an n-type region having an active layer in between, a metal contact on the p-type region (anode contact) and a metal contact on the n-type region (cathode contact). The LED die is generally provided by wafer sawing an LED wafer having many thousands of LED die. The first substrate is optically transparent in the wavelength range for the LED emission and can generally comprise materials such as Al₂O₃ (sapphire), GaN (gallium nitride), SiC (silicon carbide) or Si (silicon).

Step 102 comprises printing a metal paste or a metal ink on the first contact pad and second contact pad on a top surface of a package substrate or lead frame substrate including a dielectric material having a first metal through via (post) contacting the first contact pad and second metal through via (post) contacting the first contact pad. The printing can comprise screen printing or ink jet printing

Examples of pastes that can be used include common SAC alloys (Sn, Ag, Cu) used in the industry, and specialized pastes such as provided by Ormet and Senju Companies. The flux and other organic components assist in the distribution of the metal system to the desired area and help activate the surfaces to be bonded together. The solvent and flux selected will generally activate any Cu, Au, Ag or other metal finish found on the metal pads. For printability the metal ink utilized typically comprises a solvent (10-90 wt. %), metal particles (0.5-90%), dispersant (0.1-5%), and optional surfactant (0-5%) and binder (0-10%). Example inks include PVNanocell conductive silver ink (150-TNG), Intrisiq conductive copper ink, and Cabot CCI-300 conductive silver ink.

To provide a low resistance contact with the metal contact pads that the ink is printed over, one of the following is generally provided or performed:
i) The conductive ink has a component which dissolves/etches away the native oxide that is on aluminum/copper/gold contact pads such as an acid including phosphoric acid, hydrofluoric acid, or acetic acid, a base such as ammonium hydroxide, or an oxidizer such as hydrogen peroxide.
ii) A plasma step of the metal contact pads performed right before printing of the conductive ink for interconnects using a plasma, such as Ar, CHF₃, or O₂, or combination thereof. For this, the ink printer can be outfitted with an atmospheric plasma print head which passes in front of the conductive material print head at a time before printing.
iii) A high temperature or laser/xenon flash cure performed which can diffuse the metal ink through the thin native oxide layer on the metal posts.

One particular metal paste has a Cu to solder ratio (that allows a low reflow temperature, and once reflowed maintain integrity at subsequent higher temperature reflow cycles. A typical material does have Cu—SAC (Sn, Pb, Cu), but Cu in much lower ratio (0.5% to 0.6%) A distinction is that the alloy used to bond is 1) capable of low temp reflow, 2) stable at subsequent higher temps due to ratio of metals used, 3) low cost due to use of widely available metal systems (Cu and solder), 4) allows interconnect from the LED die to substrate via paste only (no need for a bump on the LED die).

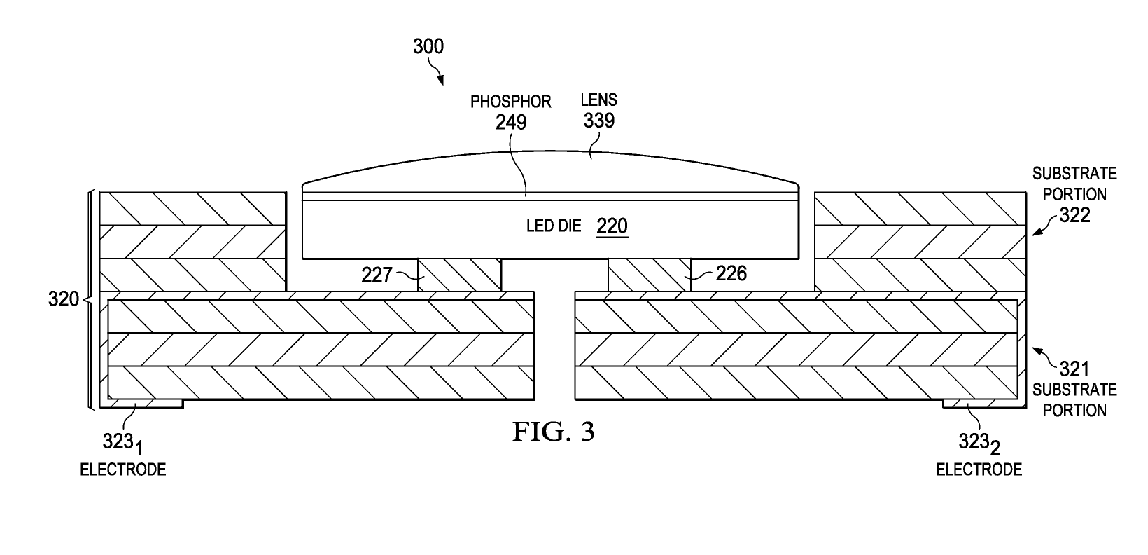

The package substrate may comprise an organic substrate which is flexible, such as polyimide, polyester, or a conventional epoxy-glass resin-based material, for example based on BT resin which is a high heat resistant thermosetting resin of the additional polymerization type with two main components B (Bismaleimide) and T (Triazine Resin). Other example organic substrates include FR4 (glass-reinforced epoxy laminate sheets), or a poly(ethylene terephthalate) (PET) type-material. Alternatively the package substrate may be comprised of a rigid material such as ceramic, or that of a printed circuit board (PCB). One rigid package substrate arrangement is a build-up layer ceramic substrate that provides electrodes (see FIG. 3 described below).

The metal paste can comprise an organic electrically conductive paste obtained by adding a thermosetting resin, such as epoxy resin, phenol resin or polyphenylene sulfide (PPS) to metal particles. The thermosetting resin may be a high molecular weight substance which is a liquid at ambient temperature but cures on heating. As such, the thermosetting resin can include phenolic resins, acrylic resins, epoxy resins, polyester resins and xlene resins, to name but a few. When the resin component is a thermosetting resin alone, the thermosetting resin is generally used in the range of 15 to 5 weight percent relative to the metal. The metal particles can comprise copper, platinum, platinum-gold, platinum-iridium or other refractory metallic, metallic alloy paste, silver, silver-palladium, gold, gold-palladium or mixtures thereof, tungsten, tungsten-molybdenum, niobium or other refractory metal system. The metal paste can include an adhesion improver for improving adhesion to the substrate, such as one or a combination of standard glass components such as PbO, B₂O₃, ZnO, CaO, SiO₂ and Al₂O₃. In one particular embodiment the metal paste comprises copper and is Pb-free.

The method can further depositing a solder wetable metal finish on the anode contact and on the cathode contact. The method can also further comprise phosphor coating the LED die before the flip chip LED die placing step (step 103) described below. For example, the phosphor can be selected a material that produces red, yellow, yellow-green (e.g., using a YAG phosphor), or green light from a blue LED, and be formed to conformably coat the LED die. Depending on the phosphor material a 420 nm to 650 nm range may be obtained (blue to red). One example application uses a phosphor material that is in blue range (sub 500 nm). A generally suitable phosphor deposition technique is electrophoretic deposition (EPD). The method can also comprise laser or mechanically chamfering the edges of LED die before step 103 to enable improved light performance by disrupting the crystal lattice.

Step 103 comprises flip chip placing the LED die such that its anode contact is on the first contact pad and its cathode contact is on the second contact pad. Pick and place can be used for step 103, such as with pick and place equipment from Shinkawa or Bestem. Step 104 comprises reflowing the metal paste or curing the metal ink to form a metal residual. The reflowing or curing can be performed at a low temperature, (such as 210° C. to 220° C. or less so as to not damage the phosphor coating that may be on the LED die. The method can further comprise step 105 which comprises placing a lens on the LED die after reflowing or curing (see lens 339 in FIG. 3 described below). The lens can comprise silicone in one particular embodiment.

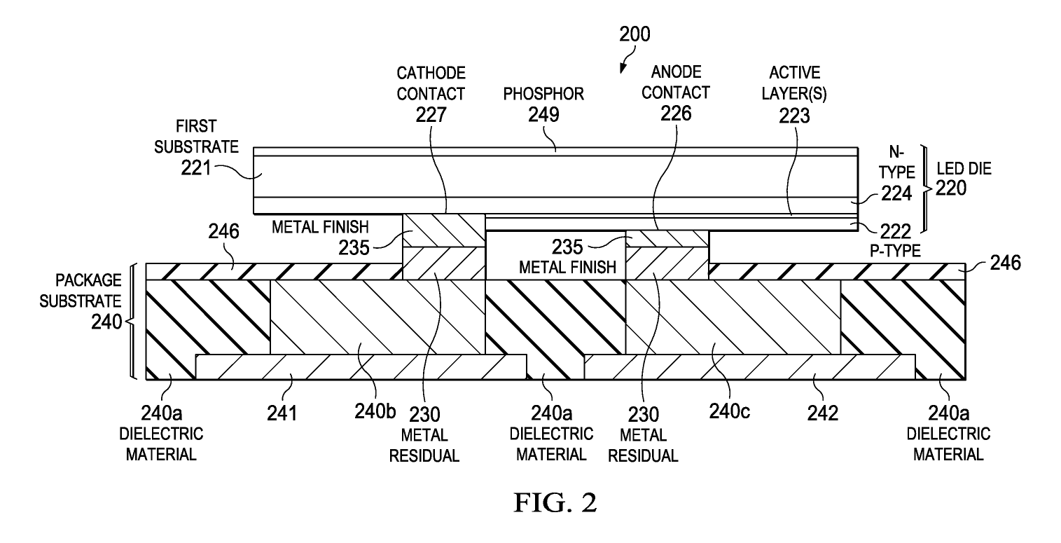

FIG. 2 is a cross sectional view of an example flip chip LED package 200 including an LED die 220 interconnected by an interconnect paste or ink residual (metal residual) 230 to a package substrate 240 that can comprise an organic substrate, ceramic, or a printed circuit board (PCB) substrate, according to an example embodiment. The package substrate is generally 60 μm to 200 μm thick and a total thickness of the LED package 200 is generally less than 400 μm.

The LED die includes a first substrate 221, a p-type region 222 and an n-type region 224 having an active layer 223 in between. The active layer 223 can comprise a multiquantum-well (MQW). A metal contact is on the p-type region 222 shown as anode contact 226 and a metal contact is on the n-type region 224 is shown as a cathode contact 227. There is shown a metal finish 235 that is generally a solder wet-able metal finish (e.g., Au/Sn) that is on the anode contact 226 and on the cathode contact 227. A phosphor layer 249 is shown on a top of the first substrate 221.

The package substrate 240 includes a dielectric material 240a having a first metal through via (first metal post) 240b and second metal through via (second metal post) 240c spaced apart from one another and embedded in the dielectric material 240a. A first metal pad 241 is on a bottom side of the first metal post 240b and a second metal pad 242 is on a bottom side of the second metal post 240c.

The metal residual 230 is between the anode contact 226 and the first metal post 240b and between the cathode contact 227 and the second metal post 240c. Lateral to the metal residual 230 on the dielectric material 240a and the first metal post 240b and on the dielectric material 240a and the second metal post 240c except between the metal residual 230 is a dielectric layer 246 that can comprise solder resist/soldermask in one embodiment. The soldermask layer (optional) is for preventing the paste or ink from flowing.

The flip chip LED package 200 is thus exclusive of underfill. Underfill is not needed because inherent to LED the bond pads on the die are relatively quite large and even larger on the substrate. The material is reflowed (or cured) forming a very large interconnect (bonded) area. This large area allows for mechanical strength in the joint that is generally not available in smaller, tighter pitch Si-based devices. In addition the material can be selected has a low modulus to absorb stress on the joint due to coefficient of thermal expansion (CTE) mismatch. In the case of Cu paste, the Cu portion of the paste material makes this mismatch as small as possible further reducing stress on the joint. The anode contact 226, cathode contact 227, metal residual 230, first metal post 240b, second metal post 240c, first metal pad 241 and second metal pad 242 can all be non-circular in cross sectional shape, such as rectangular in shape or other shape to maximize the contact area.

It should be clear to those having ordinary skill in the art the package substrate 240 show in FIG. 2 can be replaced by a lead frame package, including either leaded or non-leaded packages (e.g., quad flat no-lead (QFN)) using a related flip-chip on lead frame method of attaching the LED die to the lead frame. In that case the anode and cathode contacts of the LED die are directly connected by disclosed metal residual to respective lead fingers (leads) of the lead frame.

FIG. 3 is a cross sectional view of an example flip chip LED package 300 that includes build-up layer ceramic substrate (ceramic substrate) 320, according to another example embodiment. Ceramic substrate 320 includes substrate portion 321 and 322 which are each shown including sub-portions. Substrate 320 includes an electrode 323₁ between substrate portion 321 and 322 extending along the sidewall of the substrate portion 321 to a bottom surface of the substrate portion 321 that also extends on a top side of substrate portion 321 to contact the cathode contact 227 of the LED die 220 and an electrode 323₂between substrate portion 321 and 322 extending along the sidewall of the substrate portion 321 to a bottom surface of the substrate portion 321 that also extends on a top side of substrate portion 321 to contact the anode contact 227 of the LED die 220. A lens 339 is shown on the phosphor layer 249 which is on top surface of LED die 220.

Advantages of disclosed embodiments include applicability to a wide range of semiconductor devices besides LEDs, such as power devices w/ large bond pads for thermal/electrical transmission but being particularly beneficial for LEDs because of several reasons described below. Disclosed embodiments leverage large die pads existing on conventional LED die (2 pad, anode/cathode configuration) that allow for large areas for joint formation, and provides a low stress from the low temperature die attach that removes the need for underfill. The low temperature die attach allows a pre-coat phosphor layer (over the LED die) to remain intact. There is high temperature stability after first reflow (die attach) which enables joint integrity after second level reflow (metal paste sintering or ink curing). An optional low cost (organic) substrate provides excellent thermal management due to the ability to form large vias w/Cu (highly thermally conductive). The method can use a low cost assembly equipment set for screen printing the metal paste, LED die placement and reflow. Disclosed embodiments are also compatible with a variety of back-end process for LED die including phosphor coating, lens placement on the LED die, and strip assembly.

Disclosed embodiments can be integrated into a variety of assembly flows to form a variety of different optoelectronic devices beyond LED packages as described above or to form semiconductor electronic packaged devices, generally for any semiconductor device with large bond pads, such as power semiconductor devices. The assembly can comprise single semiconductor die or multiple semiconductor die, such as PoP configurations comprising a plurality of stacked semiconductor die. A variety of package substrates may be used.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

1. A flip chip light emitting diode (LED) package, comprising:
an LED die comprising a first substrate, a p-type region and an n-type region having an active layer in between, a metal contact on said p-type region (anode contact) and a metal contact on said n-type region (cathode contact);
a package substrate or lead frame package including a dielectric material having a first metal through via (first metal post) and second metal through via (second metal post) spaced apart from one another and embedded in said dielectric material;
a first metal pad on a bottom side of said first metal post and a second metal pad on a bottom side of said second metal post, and an interconnect paste or ink residual including metal (metal residual) between said anode contact and said first metal post and between said cathode contact and said second metal post.

2. The flip chip LED package of claim 1, wherein said first substrate comprises sapphire or GaN, SiC (silicon carbide) or Si (silicon).

3. The flip chip LED package of claim 1, further comprising a phosphor layer over said LED die.

4. The flip chip LED package of claim 1, wherein said package substrate comprises an organic substrate.

5. The flip chip LED package of claim 1, wherein edges of said LED die are chamfered.

6. The flip chip LED package of claim 1, further comprising a solder wetable metal finish on said anode contact and on said cathode contact.

7. The flip chip LED package of claim 1, wherein said flip chip LED package is exclusive of underfill.

8. The flip chip LED package of claim 1, wherein said metal residual comprises copper and is Pb-free.

9. The flip chip LED package of claim 1, wherein said first metal post and said second metal post both have non-circular cross sectional shapes.

10. A method of assembling a flip chip light emitting diode (LED) package, comprising:
printing a metal paste or a metal ink on first and second contact pads on a top surface of a package substrate including a dielectric material having a first metal through via (post) contacting said first contact pad and second post contacting said first contact pad;
flip chip placing an LED die comprising a first substrate including a p-type region and an n-type region having an active layer in between, a metal contact on said p-type region (anode contact) on said first contact pad and a metal contact on said n-type region (cathode contact) on said second contact pad, and
reflowing said metal paste or curing said metal ink to form a metal residual.

11. The method of claim 10, further comprising phosphor coating said LED die before said flip chip placing.

12. The method of claim 10, further comprising placing a lens on said LED die after said reflowing or said curing.

13. The method of claim 10, wherein said package substrate comprises an organic substrate.

14. The method of claim 10, wherein said package substrate comprises a printed circuit board (PCB) or a build-up layer ceramic substrate.

15. The method of claim 10, wherein said first substrate comprises sapphire or GaN.

16. The method of claim 10, further comprising laser or mechanically chamfering edges of said LED die before said flip chip placing.

17. The method of claim 10, further comprising depositing a solder wetable metal finish on said anode contact and on said cathode contact.

18. The method of claim 10, wherein said printing comprises screen printing.

19. A flip chip light emitting diode (LED) package, comprising:
an LED die comprising a first substrate, a p-type region and an n-type region having an active layer in between, a metal contact on said p-type region (anode contact) and a metal contact on said n-type region (cathode contact);
a phosphor layer over said LED die;
a package substrate including an organic dielectric material (organic material) having a first metal through via (first metal post) and second metal through via (second metal post) spaced apart from one another and embedded in said organic material;
a first metal pad on a bottom side of said first metal post and a second metal pad on a bottom side of said second metal post, and
an interconnect metal paste or metal ink residual (metal residual) between said anode contact and said first metal post and between said cathode contact and said second metal post.

20. The flip chip LED package of claim 19, wherein said first substrate comprises sapphire.
